(19) United States
(12) Patent Application Publication
(10) Pub. No.: US 2025/0253303 A1
(43) Pub. Date: Aug. 7, 2025

(54) INTEGRATED LC DEVICE AND MOUNTING STRUCTURE

(71) Applicant: Murata Manufacturing Co., Ltd., Kyoto (JP)

(72) Inventors: Takuo WAKAOKA, Kyoto (JP); Yoshimasa YOSHIOKA, Kyoto (JP); Ryo KASAI, Kyoto (JP); Teiji YAMAMOTO, Kyoto (JP)

(21) Appl. No.: 19/184,309

(22) Filed: Apr. 21, 2025

Related U.S. Application Data
(63) Continuation of application No. PCT/JP2024/022953, filed on Jun. 25, 2024.

(30) Foreign Application Priority Data
Dec. 18, 2023 (JP) 2023-213021

(51) Int. Cl. H01L 25/18; H01L 23/538; H10B 80/00; H10D 1/20; H10D 1/68

(52) U.S. Cl. CPC H01L 25/18; H01L 23/5385; H10D 1/20; H10D 1/68; H10B 80/00

(57) ABSTRACT

An integrated LC device includes: a capacitor layer which has a first surface and a second surface, the first surface and the second surface facing each other in a thickness direction; a rewiring layer which is provided on the first surface of the capacitor layer; and an inductor layer which is provided on the second surface of the capacitor layer. The capacitor layer includes a capacitor portion having an anode and a cathode, a first insulating portion provided around the capacitor portion, and a first via conductor portion penetrating through the first insulating portion in the thickness direction at a position separate from the capacitor portion in a plane direction orthogonal to the thickness direction. The rewiring layer includes a wiring portion and a second insulating portion provided around the wiring portion. The inductor layer 30 includes an inductor portion and a third insulating portion provided around the inductor portion.

### CROSS REFERENCE TO RELATED APPLICATION

This is a continuation of International Application No. PCT/JP2024/022953 filed on Jun. 25, 2024 which claims priority from Japanese Patent Application No. 2023-213021 filed on Dec. 18, 2023. The contents of these applications are incorporated herein by reference in their entireties.

### BACKGROUND OF THE DISCLOSURE

### Field of the Disclosure

The present disclosure relates to an integrated LC device and a mounting structure.

### Description of the Related Art

Japanese Patent No. 6165866 discloses a device including a circuit board, which has a first surface and a second surface being an opposite side to the first surface, and a passive device integrated on the circuit board. The passive device includes: an input terminal, which is configured to couple with power of a die; an output terminal, which is electrically coupled with the input terminal; and an electrical routing mechanism, which is arranged between the first surface and the second surface of the circuit board and coupled with the input terminal and the output terminal to route the power between the input terminal and the output terminal. The input terminal includes a surface configured to receive solder ball connections of a die package assembly including the die.

### BRIEF SUMMARY OF THE DISCLOSURE

Japanese Patent No. 6165866 discloses an integrated circuit (IC) package assembly that includes a die package assembly, which includes a package substrate having one or more dies mounted thereon, and a circuit board coupled to the die package assembly, as an example. It is described in Japanese Patent No. 6165866 that the die may be a processor, a memory, or an application specific integrated circuit (ASIC) in some embodiments.

It is also described in Japanese Patent No. 6165866 that the circuit board may include one or more passive devices integrated on the circuit board and, in some embodiments, the passive device includes one or more of an inductor, a capacitor, a resistor, and the like.

For example, in a power supply line from a voltage conversion module (VRM) to a processor, a combination of an inductor and a capacitor is used as a passive device. It is desired to reduce the parasitic resistance and the parasitic inductance of the current path in this configuration.

The present disclosure has been made to solve the above-mentioned problems, and a possible benefit of the present disclosure is to provide an integrated LC device capable of reducing parasitic resistance and parasitic inductance of a current path. It is a further possible benefit of the present disclosure to provide a mounting structure which includes an interposer including the integrated LC device.

An integrated LC device of the present disclosure includes: a capacitor layer which has a first surface and a second surface, the first surface and the second surface facing each other in a thickness direction; a rewiring layer which is provided on the first surface of the capacitor layer; and an inductor layer which is provided on the second surface of the capacitor layer. The capacitor layer includes a capacitor portion having an anode and a cathode, a first insulating portion provided around the capacitor portion, and a first via conductor portion penetrating through the first insulating portion in the thickness direction at a position separate from the capacitor portion in a plane direction orthogonal to the thickness direction. The rewiring layer includes a wiring portion and a second insulating portion provided around the wiring portion. The inductor layer includes an inductor portion and a third insulating portion provided around the inductor portion. The inductor portion is electrically connected to the anode of the capacitor portion positioned on the first surface of the capacitor layer via the first via conductor portion and the wiring portion.

A mounting structure of the present disclosure includes: an interposer which includes the integrated LC device of the present disclosure; a package substrate which is arranged on a main surface of the interposer on a side closer to the inductor layer; and a processor which is arranged on a main surface of the interposer on a side closer to the capacitor layer.

According to the present disclosure, an integrated LC device capable of reducing parasitic resistance and parasitic inductance of a current path can be provided. Further, according to the present disclosure, a mounting structure which includes an interposer including the integrated LC device can be provided.

### BRIEF DESCRIPTION OF THE SEVERAL VIEWS OF THE DRAWINGS

FIG. 1 is a sectional view schematically showing an example of an integrated LC device according to a first embodiment of the present disclosure.

FIG. 2 is an equivalent circuit diagram of an integrated LC device 1 shown in FIG. 1.

FIG. 3 is a schematic diagram showing an example of an electronic circuit including the integrated LC device 1 shown in FIG. 1.

FIG. 4 is a sectional view schematically showing an example of a capacitor portion.

FIG. 5 is a sectional view schematically showing an example of a MIM structure.

FIG. 6 is a perspective view schematically showing an example of an inductor portion.

FIG. 7 is a perspective view schematically showing another example of the inductor portion.

FIG. 8 is a perspective view schematically showing still another example of the inductor portion.

FIG. 9 is a sectional view schematically showing another example of the integrated LC device according to the first embodiment of the present disclosure.

FIG. 10 is a sectional view schematically showing an example of a step of forming a capacitor layer.

FIG. 11 is a sectional view schematically showing an example of a step of forming a rewiring layer.

FIG. 12 is a sectional view schematically showing an example of a step of arranging a support member.

FIG. 13 is a sectional view schematically showing an example of a step of removing a substrate.

FIG. 14 is a sectional view schematically showing an example of a step of forming a third insulating portion and a second via conductor portion.

FIG. 15 is a sectional view schematically showing an example of a step of forming an inductor portion.

FIG. 16 is a sectional view schematically showing an example of a step of forming a first bump.

FIG. 17 is a sectional view schematically showing an example of a step of removing the support member.

FIG. 18 is a sectional view schematically showing an example of an integrated LC device according to a second embodiment of the present disclosure.

FIG. 19 is a sectional view schematically showing another example of the integrated LC device according to the second embodiment of the present disclosure.

FIG. 20 is a sectional view schematically showing an example of an integrated LC device according to a third embodiment of the present disclosure.

FIG. 21 is a sectional view schematically showing an example of a mounting structure of the present disclosure.

FIG. 22 is a sectional view schematically showing an example of an integrated LC device included in an interposer constituting the mounting structure shown in FIG. 21.

FIG. 23 is a sectional view schematically showing a first modification of the mounting structure of the present disclosure.

FIG. 24 is a sectional view schematically showing an example of an integrated LC device included in an interposer constituting the mounting structure shown in FIG. 23.

FIG. 25 is a sectional view schematically showing a second modification of the mounting structure of the present disclosure.

FIG. 26 is a sectional view schematically showing an example of an integrated LC device included in an interposer constituting the mounting structure shown in FIG. 25.

### DETAILED DESCRIPTION OF THE DISCLOSURE

An integrated LC device and a mounting structure of the present disclosure will be described below. The present disclosure is not limited to the following embodiments and may be appropriately modified without departing from the scope of the present disclosure. Further, a combination of a plurality of preferred configurations described in the following embodiments is also included in the present disclosure.

It is needless to say that each of the embodiments described below is an example and configurations described in different embodiments can be partially replaced or combined. In a second embodiment and the subsequent embodiments, the description of the same matters as those of a first embodiment will be omitted, and different points will be mainly described. In particular, similar operations and effects obtained with similar configurations will not be described in detail for each embodiment.

In the following description, when the embodiments are not particularly distinguished from each other, they are simply referred to as “integrated LC device of the present disclosure” and “mounting structure of the present disclosure”. The shapes, arrangements, and the like of the integrated LC device and mounting structure of the present disclosure are not limited to the examples shown in the drawings.

In the present specification, terms indicating a relationship between elements (for example, “perpendicular”, “parallel”, “orthogonal”, and so forth) and terms indicating shapes of elements are not expressions indicating only strict meanings, but are expressions indicating substantially the same range, for example, including a difference of approximately several %.

The drawings described below are schematic diagrams, and the dimensions, the scale of the aspect ratio, and the like may be different from those of an actual product. In the drawings, the same or corresponding parts are denoted by the same reference characters. In addition, the same elements are denoted by the same reference characters in the drawings, and redundant description thereof will be omitted.

### Integrated LC Device

An integrated LC device of the present disclosure includes a capacitor layer which has a first surface and a second surface facing each other in a thickness direction, a rewiring layer which is provided on the first surface of the capacitor layer, and an inductor layer which is provided on the second surface of the capacitor layer.

### First Embodiment

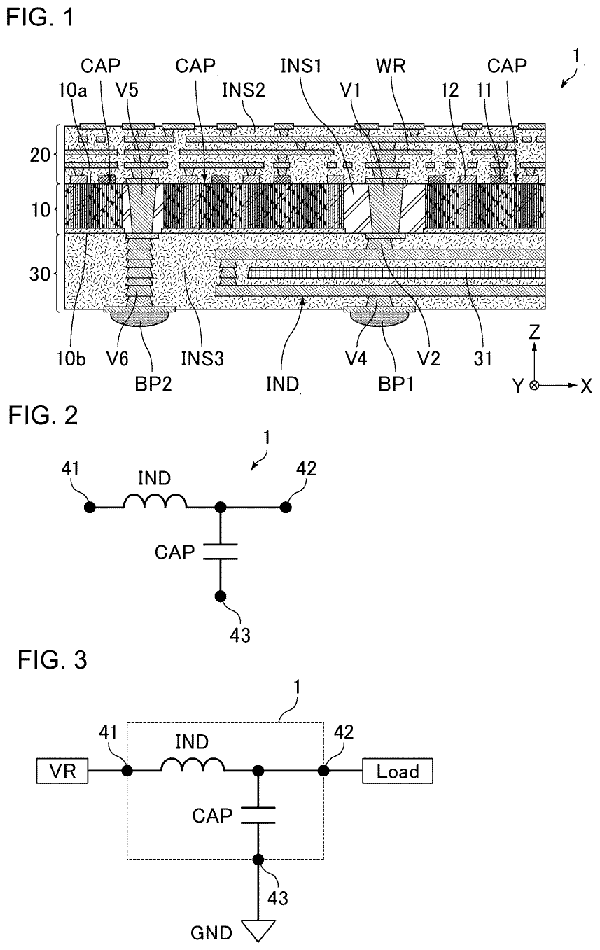

FIG. 1 is a sectional view schematically showing an example of an integrated LC device according to the first embodiment of the present disclosure.

An integrated LC device 1 shown in FIG. 1 includes a capacitor layer 10, a rewiring layer 20, and an inductor layer 30.

The capacitor layer 10 has a first surface 10a and a second surface 10b which face each other in the thickness direction (the Z-axis direction in FIG. 1).

The capacitor layer 10 includes: a capacitor portion CAP, which has anodes 11 and cathodes 12; a first insulating portion INS1, which is provided around the capacitor portion CAP; and a first via conductor portion V1, which penetrates through the first insulating portion INS1 in the thickness direction at a position separate from the capacitor portion CAP in a plane direction orthogonal to the thickness direction (XY-plane direction in FIG. 1). The capacitor layer 10 may include a plurality of capacitor portions CAP. The configuration, shape, and the like of the capacitor portion CAP are not particularly limited. In addition, the capacitor layer 10 may include a plurality of first via conductor portions V1. The first via conductor portion V1 may have a tapered shape.

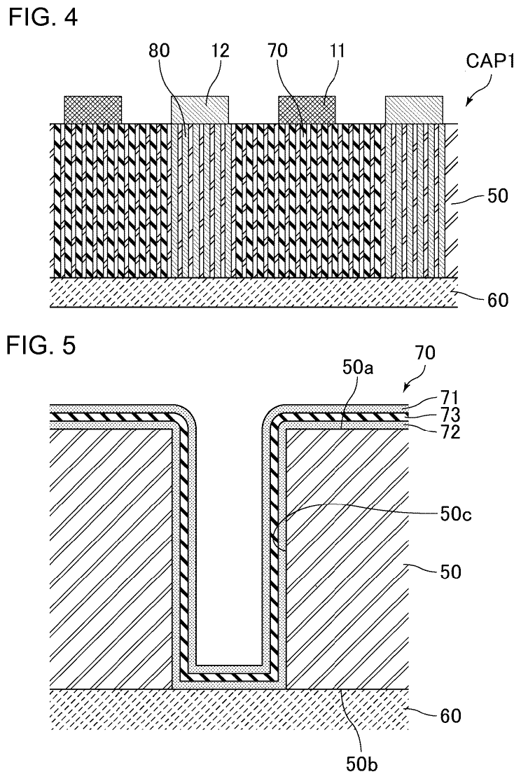

In the example shown in FIG. 1, the anodes 11 of the capacitor portion CAP are positioned on the first surface 10a of the capacitor layer 10. The cathodes 12 of the capacitor portion CAP may be positioned on the first surface 10a of the capacitor layer 10. A via conductor, which penetrates through the inductor layer 30 in the thickness direction, may be provided below a conductor layer 60 (see FIG. 4) which is positioned below the cathode 12. In this configuration, the via conductor is provided in a region of the inductor layer 30 where an inductor portion IND is not provided (a region on the far side or the near side of the paper surface in FIG. 1).

The rewiring layer 20 is provided on the first surface 10a of the capacitor layer 10.

The rewiring layer 20 includes a wiring portion WR and a second insulating portion INS2 provided around the wiring portion WR. The wiring portion WR includes, for example, conductor layers along the plane direction and via conductors connecting the conductor layers to each other.

The inductor layer 30 is provided on the second surface 10b of the capacitor layer 10.

The inductor layer 30 includes the inductor portion IND and a third insulating portion INS3 provided around the inductor portion IND. The inductor layer 30 may include a plurality of inductor portions IND. The configuration, shape, and the like of the inductor portion IND are not particularly limited.

As shown in FIG. 1, the inductor portion IND is electrically connected to the anodes 11 of the capacitor portion CAP positioned on the first surface 10a of the capacitor layer 10 via the first via conductor portion V1 and the wiring portion WR.

In the integrated LC device 1, the inductor portion IND is electrically connected to the anodes 11 of the capacitor portion CAP positioned on the first surface 10a of the capacitor layer 10 via the first via conductor portion V1 and the wiring portion WR. Accordingly, a current path between the inductor portion IND and the capacitor portion CAP is shortened, and thus the parasitic resistance and the parasitic inductance of the current path can be reduced.

Further, the above-described configuration of the integrated LC device 1 can realize provision of a thin and high-performance (high capacitance and high inductance) integrated LC device.

FIG. 2 is an equivalent circuit diagram of the integrated LC device 1 shown in FIG. 1.

The inductor portion IND is connected between a first external terminal 41 and a second external terminal 42. In the example shown in FIG. 1, a first bump BP1 is provided as the first external terminal 41, but the form of the first external terminal 41 is not particularly limited. Similarly, the form of the second external terminal 42 is not particularly limited.

Meanwhile, the capacitor portion CAP is connected between the second external terminal 42 and a third external terminal 43. The form of the third external terminal 43 is not particularly limited.

FIG. 3 is a schematic diagram showing an example of an electronic circuit including the integrated LC device 1 shown in FIG. 1.

In the example shown in FIG. 3, the inductor portion IND is connected to a voltage regulator VR at the first external terminal 41 and is connected to a load Load at the second external terminal 42. Meanwhile, the capacitor portion CAP is connected to the load Load at the second external terminal 42 and is connected to a ground GND at the third external terminal 43.

The voltage regulator VR includes an active device such as a semiconductor switching device, and controls the duty of the active device so as to adjust a direct current voltage supplied from the outside to a voltage level suitable for the load Load.

The load Load is, for example, a semiconductor integrated circuit such as a logical operation circuit and a memory circuit.

As shown in FIG. 1, the inductor portion IND may include a magnetic layer 31 along the plane direction. In this configuration, the inductance can be increased.

The inductor layer 30 may further include a second via conductor portion V2 penetrating through the third insulating portion INS3 in the thickness direction between the inductor portion IND and the first via conductor portion V1. In this configuration, the inductor portion IND is electrically connected to the first via conductor portion V1 via the second via conductor portion V2. The second via conductor portion V2 may have a tapered shape.

As shown in FIG. 1, in the cross section along the thickness direction, the center line of the second via conductor portion V2 may be shifted from the center line of the first via conductor portion V1. Alternatively, the center line of the second via conductor portion V2 may coincide with the center line of the first via conductor portion V1 in the cross section along the thickness direction.

The diameter of the second via conductor portion V2 may be the same as the diameter of the first via conductor portion V1, may be smaller than the diameter of the first via conductor portion V1, or may be larger than the diameter of the first via conductor portion V1.

The height of the second via conductor portion V2 may be the same as the height of the first via conductor portion V1, may be smaller than the height of the first via conductor portion V1, or may be larger than the height of the first via conductor portion V1.

The material of the second via conductor portion V2 may be the same as or different from the material of the first via conductor portion V1.

The third insulating portion INS3 may include one layer of insulating layer between the capacitor portion CAP and the inductor portion IND, as shown in FIG. 1. In other words, one layer of second via conductor portion V2 may be provided between the capacitor portion CAP and the inductor portion IND. In this configuration, the current path between the inductor portion IND and the capacitor portion CAP can be shortened.

The third insulating portion INS3 may be made of an inorganic material containing a Si element. Examples of the inorganic material containing a Si element include silicon oxides such as SiO₂. Here, the third insulating portion INS3 may include an inorganic insulating layer or an organic insulating layer.

The inductor layer 30 may further include a fourth via conductor portion V4 penetrating through the third insulating portion INS3 in the thickness direction between the inductor portion IND and the first bump BP1. In this configuration, the inductor portion IND is electrically connected to the first bump BP1 via the fourth via conductor portion V4. The fourth via conductor portion V4 may have a tapered shape.

In the cross section along the thickness direction, the center line of the fourth via conductor portion V4 may be shifted from or coincide with the center line of the second via conductor portion V2.

The diameter of the fourth via conductor portion V4 may be the same as the diameter of the second via conductor portion V2, may be smaller than the diameter of the second via conductor portion V2, or may be larger than the diameter of the second via conductor portion V2.

The height of the fourth via conductor portion V4 may be the same as the height of the second via conductor portion V2, may be smaller than the height of the second via conductor portion V2, or may be larger than the height of the second via conductor portion V2.

The material of the fourth via conductor portion V4 may be the same as or different from the material of the second via conductor portion V2.

The capacitor layer 10 may further include a fifth via conductor portion V5, which penetrates through the first insulating portion INS1 in the thickness direction, at a position separate from the capacitor portion CAP and the first via conductor portion V1 in the plane direction. The fifth via conductor portion V5 is electrically connected to the wiring portion WR of the rewiring layer 20. The fifth via conductor portion V5 may have a tapered shape.

The diameter of the fifth via conductor portion V5 may be the same as the diameter of the first via conductor portion V1, may be smaller than the diameter of the first via conductor portion V1, or may be larger than the diameter of the first via conductor portion V1.

The height of the fifth via conductor portion V5 may be the same as the height of the first via conductor portion V1, may be smaller than the height of the first via conductor portion V1, or may be larger than the height of the first via conductor portion V1.

The material of the fifth via conductor portion V5 may be the same as or different from the material of the first via conductor portion V1.

The inductor layer 30 may further include a sixth via conductor portion V6, which penetrates through the third insulating portion INS3 in the thickness direction, at a position separate from the inductor portion IND in the plane direction. The sixth via conductor portion V6 is electrically connected to the fifth via conductor portion V5. The sixth via conductor portion V6 may have a tapered shape. In the example shown in FIG. 1, two or more layers of sixth via conductor portions V6 are provided in the thickness direction.

As shown in FIG. 1, in the cross section along the thickness direction, the center line of the sixth via conductor portion V6 may be shifted from the center line of the fifth via conductor portion V5. Alternatively, the center line of the sixth via conductor portion V6 may coincide with the center line of the fifth via conductor portion V5 in the cross section along the thickness direction.

The diameter of the sixth via conductor portion V6 may be the same as the diameter of the fifth via conductor portion V5, may be smaller than the diameter of the fifth via conductor portion V5, or may be larger than the diameter of the fifth via conductor portion V5.

The height of the sixth via conductor portion V6 may be the same as the height of the fifth via conductor portion V5, may be smaller than the height of the fifth via conductor portion V5, or may be larger than the height of the fifth via conductor portion V5.

The material of the sixth via conductor portion V6 may be the same as or different from the material of the fifth via conductor portion V5.

The sixth via conductor portion V6 may be electrically connected to a second bump BP2. In the example shown in FIG. 1, the second bump BP2 is electrically connected to the wiring portion WR of the rewiring layer 20 via the sixth via conductor portions V6 and the fifth via conductor portion V5.

The rewiring layer 20 is a layer called a redistribution layer (RDL). The rewiring layer 20 changes the positions, intervals, and the like of electrodes provided on the surface of the capacitor layer 10. This consequently facilitates the connection of semiconductor devices such as a processor.

The second insulating portion INS2 of the rewiring layer 20 includes, for example, an organic insulating layer. The second insulating portion INS2 may include an inorganic insulating layer and an organic insulating layer.

A specific example of the capacitor portion will be described hereinafter. However, the capacitor portion is not limited to the following configuration.

The capacitor portion may have a metal-insulator-metal structure (MIM structure) of metal layer-dielectric layer-metal layer.

FIG. 4 is a sectional view schematically showing an example of the capacitor portion.

A capacitor portion CAP1 shown in FIG. 4 includes a porous layer 50 and the conductor layer 60 provided on one surface of the porous layer 50. The porous layer 50 includes an MIM structure 70 and an extended electrode 80.

FIG. 5 is a sectional view schematically showing an example of the MIM structure.

The MIM structure 70 includes a first metal layer 71, a dielectric layer 73, and a second metal layer 72 in this order. As shown in FIG. 5, the MIM structure 70 may be provided in the porous layer 50. In the example shown in FIG. 5, the porous layer 50 has a plurality of groove portions which extend in the thickness direction from an upper surface 50a to a lower surface 50b of the porous layer 50, and the MIM structure 70 is provided on an inner surface 50c of the groove portion. The shape, diameter, and the like of the groove portion of the porous layer 50 are not particularly limited.

In the example shown in FIGS. 4 and 5, the first metal layer 71 is electrically connected to the anode 11, and the second metal layer 72 is electrically connected to the cathode 12 via the conductor layer 60 and the extended electrode 80.

The groove portions of the porous layer 50 are formed by, for example, etching silicon or the like, or anodizing aluminum, silicon, cobalt, or the like.

The MIM structure 70 is formed by, for example, atomic layer deposition (ALD).

Specific examples of the inductor portion will be described hereinafter. However, the inductor portion is not limited to the following configuration.

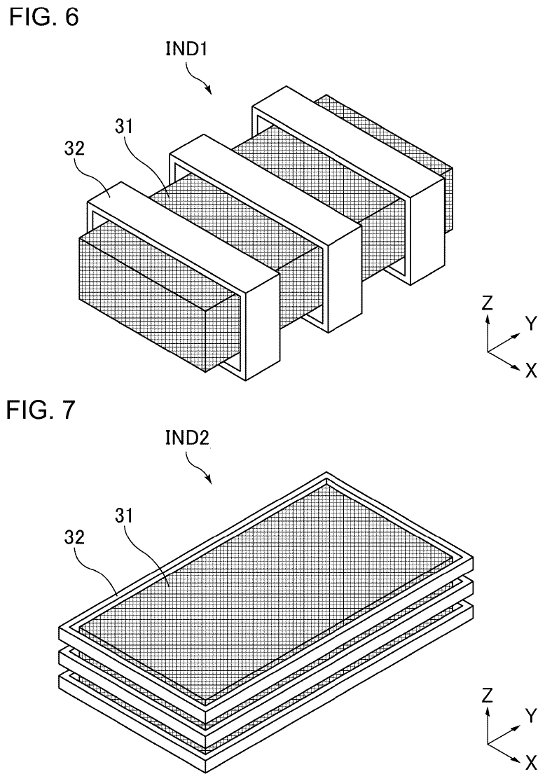

FIG. 6 is a perspective view schematically showing an example of the inductor portion.

An inductor portion IND1 shown in FIG. 6 includes the magnetic layer 31 and a coil conductor 32. In the inductor portion IND1 shown in FIG. 6, the magnetic layer 31 is wound by the coil conductor 32 when viewed in the plane direction. In this configuration, the inductance can be increased by increasing the number of turns of the coil conductor 32.

FIG. 7 is a perspective view schematically showing another example of the inductor portion.

In an inductor portion IND2 shown in FIG. 7, the magnetic layer 31 is surrounded by the coil conductor 32 when viewed in the thickness direction. In this configuration, a constant inductance can be secured and the direct current resistance (Rdc) can be reduced.

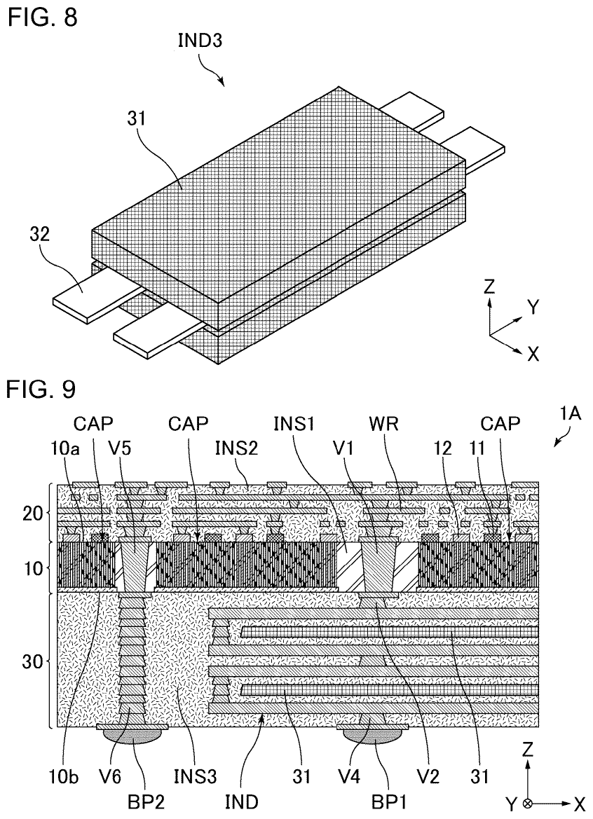

FIG. 8 is a perspective view schematically showing still another example of the inductor portion.

In an inductor portion IND3 shown in FIG. 8, the coil conductor 32 is surrounded by the magnetic layer 31. In this configuration, the direct current resistance (Rdc) can be reduced.

FIG. 9 is a sectional view schematically showing another example of the integrated LC device according to the first embodiment of the present disclosure.

In an integrated LC device 1A shown in FIG. 9, the inductor portion IND includes two or more layers of magnetic layer 31 in the thickness direction. In this configuration, the inductance can be increased by increasing the number of magnetic layers 31.

Although not shown in FIG. 9, the inductor portion IND may include two or more layers of magnetic layer 31 in the plane direction. Alternatively, the inductor portion IND may include two or more layers of magnetic layer 31 in both of the thickness direction and the plane direction.

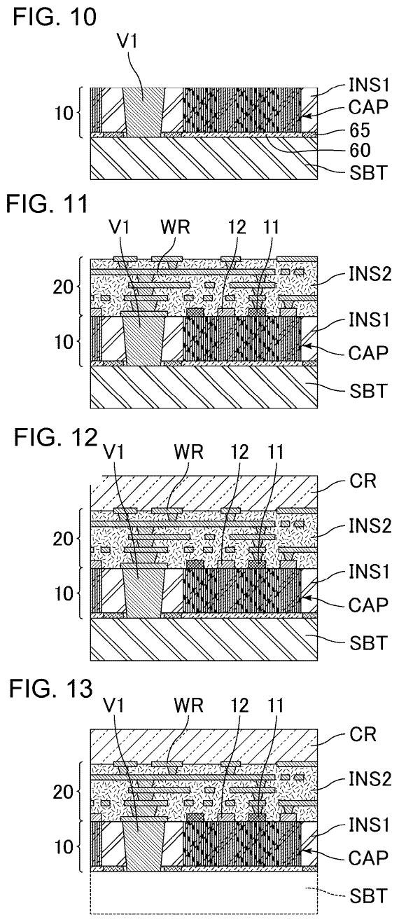

Hereinafter, an example of a method for manufacturing the integrated LC device according to the first embodiment of the present disclosure will be described. FIGS. 10 to 17 are sectional views schematically showing an example of a manufacturing process of the integrated LC device according to the first embodiment of the present disclosure.

FIG. 10 is a sectional view schematically showing an example of a step of forming a capacitor layer.

In the step shown in FIG. 10, the capacitor layer 10 including the capacitor portion CAP, the first insulating portion INS1, and the first via conductor portion V1 is formed on a surface of a substrate SBT such as a silicon substrate. As shown in FIG. 10, the conductor layer 60 and an insulating layer 65 may be provided between the substrate SBT and the capacitor layer 10.

The capacitor portion CAP may have the MIM structure (see FIGS. 4 and 5). In this configuration, the MIM structure may be provided in the porous layer.

In particular, the porous layer may have a groove portion extending in the thickness direction, and the MIM structure may be provided on the inner surface of the groove portion. The porous layer having the groove portion may be formed, for example, by etching silicon or the like, or may be formed by anodizing aluminum, silicon, cobalt, or the like.

The first via conductor portion V1 is formed by filling the porous layer with a conductive material, for example. The porous layer may be filled with the conductive material by electrolytic plating. Alternatively, the first via conductor portion V1 may be formed by removing a portion of the porous layer and filling the portion with metal by electrolytic plating. Copper or nickel may be used as the conductive material. On the other hand, a portion of the porous layer that is not filled with the conductive material can be used as the first insulating portion INS1.

FIG. 11 is a sectional view schematically showing an example of a step of forming a rewiring layer.

In the step shown in FIG. 11, the rewiring layer 20 including the wiring portion WR and the second insulating portion INS2 is formed on the surface of the capacitor layer 10. At this time, the anodes 11 and the cathodes 12 are also formed on the surface of the capacitor portion CAP. Further, a conductor layer may be formed on the surface of the first via conductor portion V1.

FIG. 12 is a sectional view schematically showing an example of a step of arranging a support member.

In the step shown in FIG. 12, a support member (carrier) CR is arranged on the surface of the rewiring layer 20. Examples of the material of the support member CR include an insulating material such as glass.

FIG. 13 is a sectional view schematically showing an example of a step of removing the substrate.

In the step shown in FIG. 13, the substrate SBT is removed by processing such as grinding. In the example shown in FIG. 13, the entire substrate SBT is removed.

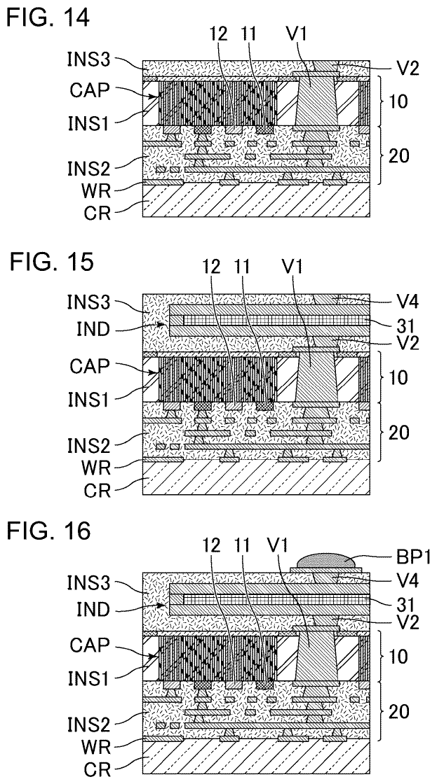

FIG. 14 is a sectional view schematically showing an example of a step of forming a third insulating portion and a second via conductor portion.

In the step shown in FIG. 14, a portion of the third insulating portion INS3 and the second via conductor portion V2 are formed on the surface of the capacitor layer 10 on the side opposite to the rewiring layer 20. At this time, a conductor layer may be formed between the first via conductor portion V1 and the second via conductor portion V2.

FIG. 15 is a sectional view schematically showing an example of a step of forming an inductor portion.

In the step shown in FIG. 15, the remaining portion of the third insulating portion INS3 and the inductor portion IND are formed. As shown in FIG. 15, the fourth via conductor portion V4 may be formed.

The inductor portion IND may include the magnetic layer 31 along the plane direction.

FIG. 16 is a sectional view schematically showing an example of a step of forming a first bump.

In the step shown in FIG. 16, the first bump BP1 electrically connected to the fourth via conductor portion V4 is formed as necessary. At this time, a conductor layer may be formed between the first bump BP1 and the fourth via conductor portion V4.

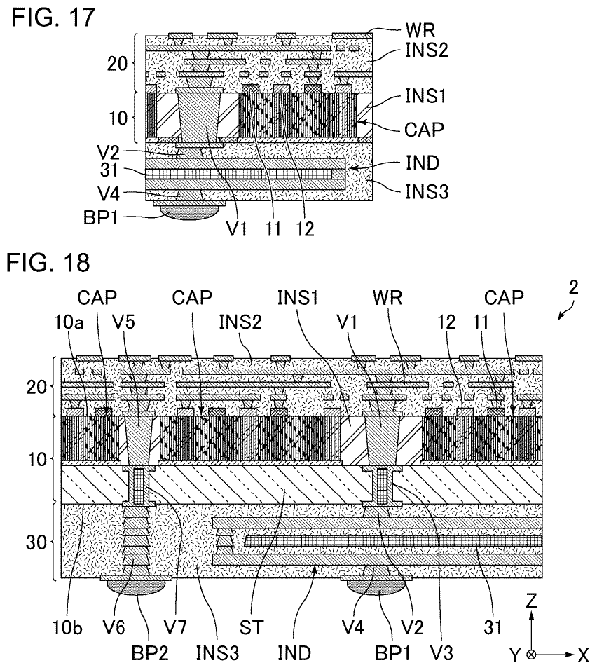

FIG. 17 is a sectional view schematically showing an example of a step of removing the support member.

In the step shown in FIG. 17, the support member CR is removed.

Through the above steps, the integrated LC device according to the first embodiment of the present disclosure is obtained. The order of the above-described steps is not particularly limited, and the order may be changed as appropriate.

### Second Embodiment

In an integrated LC device according to the second embodiment of the present disclosure, a capacitor layer includes a substrate portion and a third via conductor portion.

FIG. 18 is a sectional view schematically showing an example of an integrated LC device according to the second embodiment of the present disclosure.

In an integrated LC device 2 shown in FIG. 18, the capacitor layer 10 further includes: a substrate portion ST, which is provided on the second surface 10b so as to cover the capacitor portion CAP, the first insulating portion INS1, and the first via conductor portion V1; and a third via conductor portion V3, which penetrates through the substrate portion ST in the thickness direction between the inductor portion IND and the first via conductor portion V1. The other configurations are the same as those of the integrated LC device 1 shown in FIG. 1.

As shown in FIG. 18, the inductor portion IND is electrically connected to the first via conductor portion V1 via the third via conductor portion V3. The third via conductor portion V3 may have a tapered shape. The third via conductor portion V3 may be formed of one layer or two or more layers.

In the integrated LC device 2 shown in FIG. 18, the capacitor layer 10 includes the substrate portion ST, which can suppress warpage of the entire device.

Examples of the material of the substrate portion ST include silicon, glass, and silicon carbide, and may also include other ceramics and so forth.

In the cross section along the thickness direction, the center line of the third via conductor portion V3 may be shifted from or coincide with the center line of the first via conductor portion V1. When the inductor layer 30 includes the second via conductor portion V2, the center line of the third via conductor portion V3 may be shifted from or coincide with the center line of the second via conductor portion V2 in the cross section along the thickness direction.

The diameter of the third via conductor portion V3 may be the same as the diameter of the first via conductor portion V1, may be smaller than the diameter of the first via conductor portion V1, or may be larger than the diameter of the first via conductor portion V1. When the inductor layer 30 includes the second via conductor portion V2, the diameter of the third via conductor portion V3 may be the same as the diameter of the second via conductor portion V2, may be smaller than the diameter of the second via conductor portion V2, or may be larger than the diameter of the second via conductor portion V2.

The height of the third via conductor portion V3 may be the same as the height of the first via conductor portion V1, may be smaller than the height of the first via conductor portion V1, or may be larger than the height of the first via conductor portion V1. When the inductor layer 30 includes the second via conductor portion V2, the height of the third via conductor portion V3 may be the same as the height of the second via conductor portion V2, may be smaller than the height of the second via conductor portion V2, or may be larger than the height of the second via conductor portion V2.

The material of the third via conductor portion V3 may be the same as or different from the material of the first via conductor portion V1. When the inductor layer 30 includes the second via conductor portion V2, the material of the third via conductor portion V3 may be the same as or different from the material of the second via conductor portion V2.

As shown in FIG. 18, the capacitor layer 10 may further include a seventh via conductor portion V7 which penetrates through the substrate portion ST in the thickness direction between the fifth via conductor portion V5 and the sixth via conductor portions V6. The fifth via conductor portion V5 is electrically connected to the sixth via conductor portion V6 via the seventh via conductor portion V7. The seventh via conductor portion V7 may have a tapered shape.

In the cross section along the thickness direction, the center line of the seventh via conductor portion V7 may be shifted from or coincide with the center line of the fifth via conductor portion V5. Further, the center line of the seventh via conductor portion V7 may be shifted from or coincide with the center line of the sixth via conductor portion V6 in the cross section along the thickness direction.

The diameter of the seventh via conductor portion V7 may be the same as the diameter of the fifth via conductor portion V5, may be smaller than the diameter of the fifth via conductor portion V5, or may be larger than the diameter of the fifth via conductor portion V5. Further, the diameter of the seventh via conductor portion V7 may be the same as the diameter of the sixth via conductor portion V6, may be smaller than the diameter of the sixth via conductor portion V6, or may be larger than the diameter of the sixth via conductor portion V6.

The height of the seventh via conductor portion V7 may be the same as the height of the fifth via conductor portion V5, may be smaller than the height of the fifth via conductor portion V5, or may be larger than the height of the fifth via conductor portion V5. Further, the height of the seventh via conductor portion V7 may be the same as the height of the sixth via conductor portion V6, may be smaller than the height of the sixth via conductor portion V6, or may be larger than the height of the sixth via conductor portion V6.

The material of the seventh via conductor portion V7 may be the same as or different from the material of the fifth via conductor portion V5. Further, the material of the seventh via conductor portion V7 may be the same as or different from the material of the sixth via conductor portion V6.

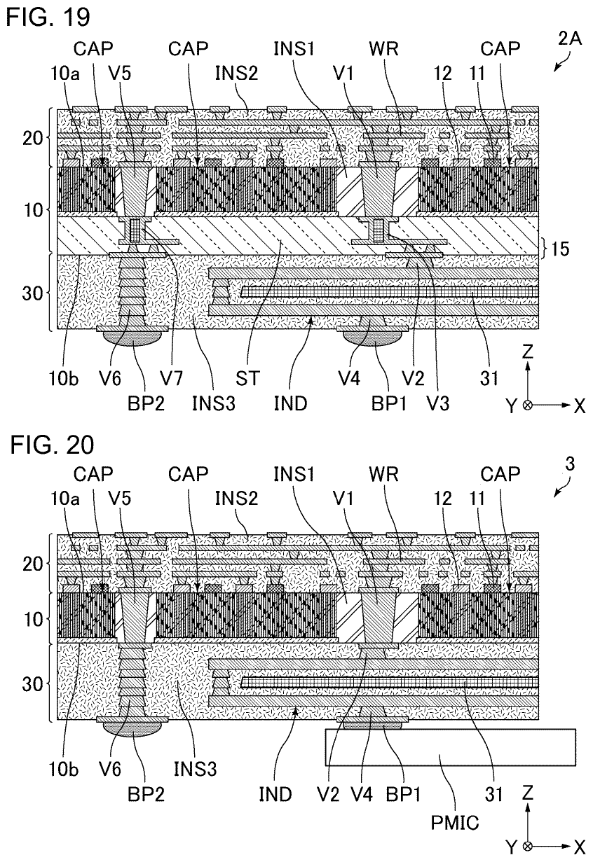

FIG. 19 is a sectional view schematically showing another example of the integrated LC device according to the second embodiment of the present disclosure.

As in an integrated LC device 2A shown in FIG. 19, a rewiring layer 15 different from the rewiring layer 20 may be provided in the substrate portion ST between the third via conductor portion V3 and the inductor portion IND. The rewiring layer 15 is provided under the third via conductor portion V3, and thus, the degree of structural freedom of the third via conductor portion V3 is increased.

The rewiring layer 15 provided in the substrate portion ST may have the same thickness as the thickness of the rewiring layer 20 or may have a thickness larger than the thickness of the rewiring layer 20, but may have a thickness smaller than the thickness of the rewiring layer 20.

### Third Embodiment

An integrated LC device according to a third embodiment of the present disclosure further includes a power management integrated circuit (power management IC).

FIG. 20 is a sectional view schematically showing an example of an integrated LC device according to the third embodiment of the present disclosure.

An integrated LC device 3 shown in FIG. 20 further includes a power management integrated circuit PMIC which is electrically connected to the inductor portion IND on the surface of the inductor layer 30 on the side opposite to the capacitor layer 10. The other configurations are the same as those of the integrated LC device 1 shown in FIG. 1.

The integrated LC device 3 shown in FIG. 20 functions as a device with a voltage conversion module. The configuration of FIG. 20 allows current to flow in the shortest path in the power supply line from the voltage conversion module (VRM) to the processor. The shortening of the current path makes it possible to reduce losses caused by Joule heat during current flow, and to reduce parasitic resistance and parasitic inductance of the current path. Accordingly, a voltage conversion module exhibiting high conversion efficiency can be obtained.

### Mounting Structure

A mounting structure of the present disclosure includes an interposer including the integrated LC device of the present disclosure, a package substrate arranged on a main surface of the interposer on a side closer to the inductor layer, and a processor arranged on a main surface of the interposer on a side closer to the capacitor layer.

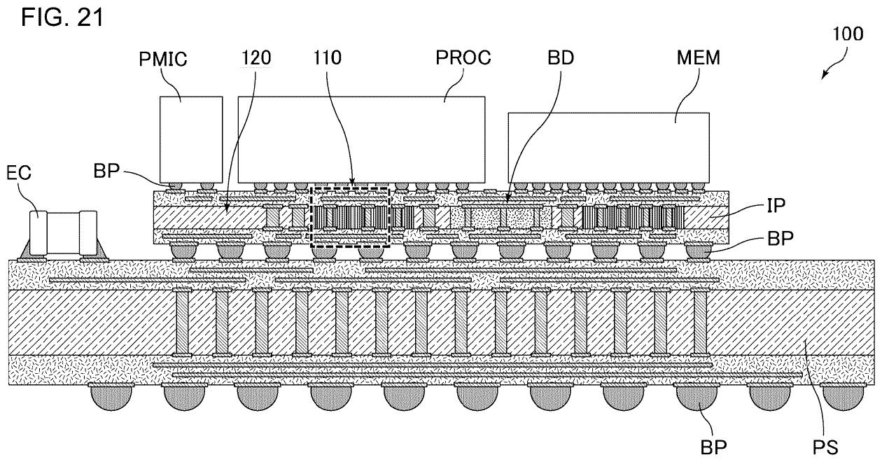

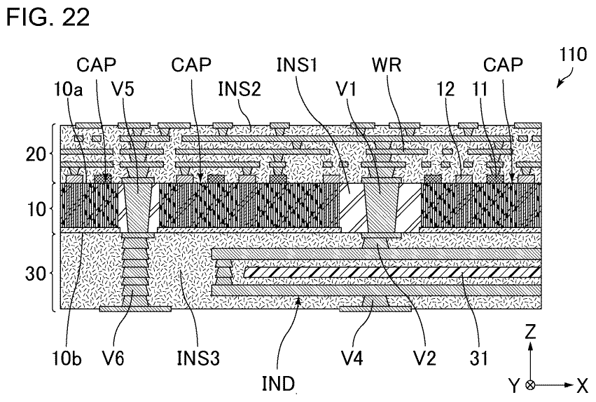

FIG. 21 is a sectional view schematically showing an example of the mounting structure of the present disclosure. FIG. 22 is a sectional view schematically showing an example of an integrated LC device included in an interposer constituting the mounting structure shown in FIG. 21. Here, FIG. 22 corresponds to a sectional view of a portion surrounded by a dashed line in FIG. 21.

A mounting structure 100 shown in FIG. 21 includes an interposer IP including an integrated LC device 110 (see FIG. 22), a package substrate PS arranged on a main surface of the interposer IP on the side closer to the inductor layer 30 (see FIG. 22), and a processor PROC arranged on a main surface of the interposer IP on the side closer to the capacitor layer 10 (see FIG. 22). The mounting structure 100 may further include a memory MEM arranged on the main surface of the interposer IP on the side closer to the capacitor layer 10 (see FIG. 22). In the example shown in FIG. 22, the integrated LC device 110 has the same configuration as the integrated LC device 1 shown in FIG. 1.

As shown in FIG. 21, the integrated LC device 110 is located at a position overlapping with the processor PROC in the thickness direction.

The mounting structure 100 shown in FIG. 21 includes the interposer IP including the thin and high-performance (high capacitance and high inductance) integrated LC device 110. In the mounting structure 100, the via conductor portion of the integrated LC device can be used as a current path for the power supply line from the voltage conversion module (VRM) to the processor, and current can be accordingly allowed to flow in the shortest path to the inductor portion IND and the capacitor portion CAP. The shortening of the current path makes it possible to reduce losses caused by Joule heat during current flow, and to reduce parasitic resistance and parasitic inductance of the current path.

In the mounting structure 100 shown in FIG. 21, the interposer IP further includes a resin layer 120 in which the integrated LC device 110 is embedded.

As shown in FIG. 21, the power management integrated circuit PMIC may be arranged on the surface of the resin layer 120.

In the example shown in FIG. 21, a wiring portion called a bridge die BD is arranged inside the resin layer 120, and the processor PROC and the memory MEM are electrically connected to each other via the bridge die BD.

When the mounting structure 100 includes the memory MEM, the interposer IP may include another integrated LC device, which is different from the integrated LC device 110, at a position overlapping with the memory MEM in the thickness direction.

For example, the interposer IP and the processor PROC, the interposer IP and the memory MEM, and the interposer IP and the power management integrated circuit PMIC are connected to each other by bumps BP.

Similarly, for example, the package substrate PS and the interposer IP are connected to each other by bumps BP. Bumps BP may be provided on the surface of the package substrate PS on the side opposite to the interposer IP.

An electronic component EC may be arranged on the surface of the package substrate PS.

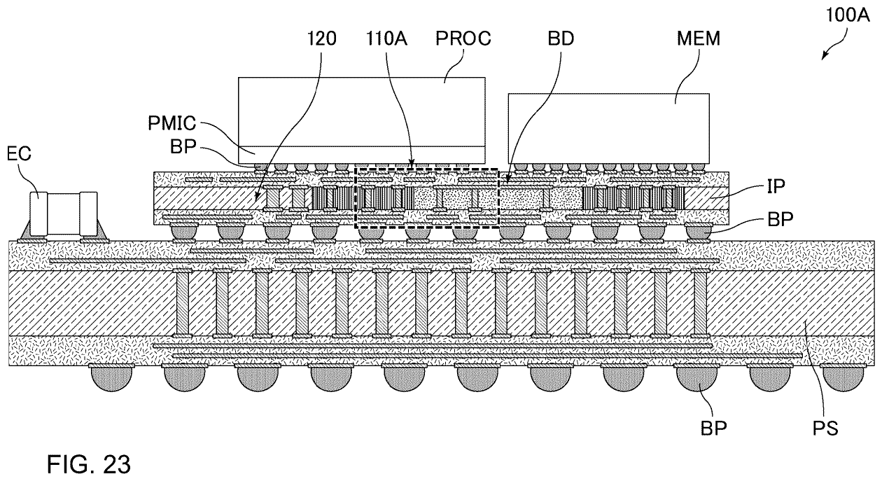

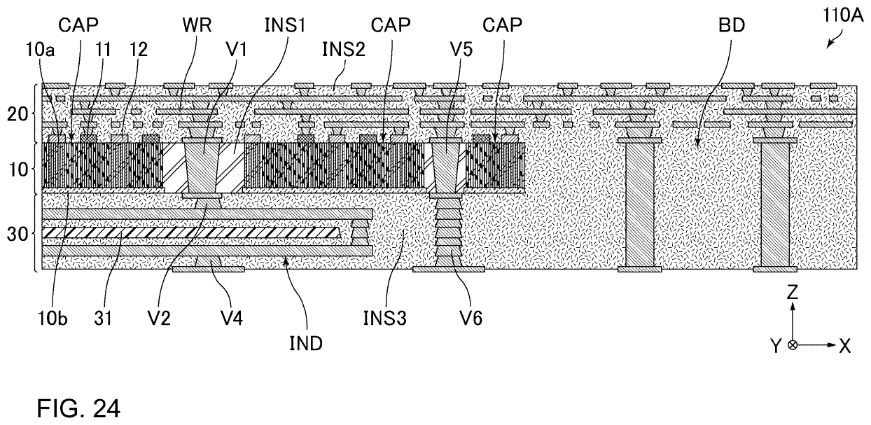

FIG. 23 is a sectional view schematically showing a first modification of the mounting structure of the present disclosure. FIG. 24 is a sectional view schematically showing an example of an integrated LC device included in an interposer constituting the mounting structure shown in FIG. 23. Here, FIG. 24 corresponds to a sectional view of a portion surrounded by a dashed line in FIG. 23.

A mounting structure 100A shown in FIG. 23 is different from the mounting structure 100 shown in FIG. 21 in that the bridge die BD is incorporated in an integrated LC device 110A (see FIG. 24) instead of being arranged inside the resin layer 120.

Specifically, as shown in FIGS. 23 and 24, the rewiring layer 20 of the integrated LC device 110A extends to a position overlapping with both of the processor PROC and the memory MEM in the thickness direction. Further, as shown in FIG. 23, the power management integrated circuit PMIC is arranged inside the processor PROC.

In the mounting structure 100A shown in FIG. 23, the rewiring layer 20 of the integrated LC device 110A is used not only as a power supply line but also as signal wiring. The capacitor portion CAP and the inductor portion IND are arranged in the vicinity of the bridge die BD, being able to reduce noise of the signal wiring between the processor PROC and the memory MEM.

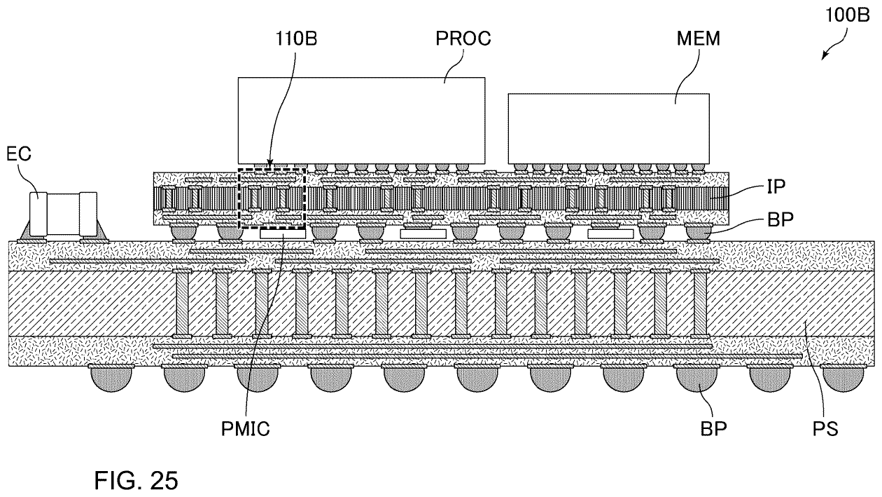

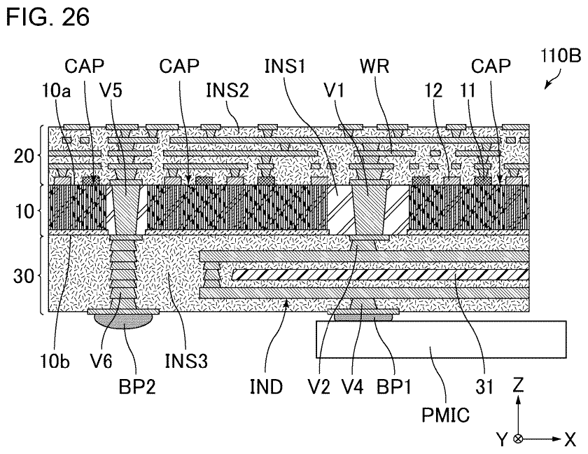

FIG. 25 is a sectional view schematically showing a second modification of the mounting structure of the present disclosure. FIG. 26 is a sectional view schematically showing an example of an integrated LC device included in an interposer constituting the mounting structure shown in FIG. 25. Here, FIG. 26 corresponds to a sectional view of a portion surrounded by a dashed line in FIG. 25.

A mounting structure 100B shown in FIG. 25 is different from the mounting structure 100 shown in FIG. 21 and the mounting structure 100A shown in FIG. 23 in that the interposer IP does not include the resin layer 120 and is composed only of an integrated LC device 110B (see FIG. 26).

In the example shown in FIG. 26, the integrated LC device 110B has the same configuration as the integrated LC device 3 shown in FIG. 20. That is, the integrated LC device 110B further includes the power management integrated circuit PMIC which is electrically connected to the inductor portion IND on the surface of the inductor layer 30 on the side opposite to the capacitor layer 10.

In the mounting structure 100B shown in FIG. 25, the integrated LC device 110B itself is used as the interposer IP. By arranging the capacitor portion CAP and the inductor portion IND directly under the signal wiring of the interposer IP, noise of the signal wiring can be reduced.

The present specification discloses the following contents.
<1> An integrated LC device including: a capacitor layer which has a first surface and a second surface, the first surface and the second surface facing each other in a thickness direction; a rewiring layer which is provided on the first surface of the capacitor layer; and an inductor layer which is provided on the second surface of the capacitor layer, in which the capacitor layer includes a capacitor portion having an anode and a cathode, a first insulating portion provided around the capacitor portion, and a first via conductor portion penetrating through the first insulating portion in the thickness direction at a position separate from the capacitor portion in a plane direction orthogonal to the thickness direction, the rewiring layer includes a wiring portion and a second insulating portion provided around the wiring portion, the inductor layer includes an inductor portion and a third insulating portion provided around the inductor portion, and the inductor portion is electrically connected to the anode of the capacitor portion positioned on the first surface of the capacitor layer via the first via conductor portion and the wiring portion.
<2> The integrated LC device according to <1>, in which the capacitor portion has a MIM structure of metal layer-dielectric layer-metal layer.
<3> The integrated LC device according to <2>, in which the MIM structure is provided in a porous layer.
<4> The integrated LC device according to <3>, in which the porous layer has a groove portion extending in the thickness direction, and the MIM structure is provided on an inner surface of the groove portion.
<5> The integrated LC device according to any one of <1> to <4>, in which the inductor layer further includes a second via conductor portion which penetrates through the third insulating portion in the thickness direction between the inductor portion and the first via conductor portion, and the inductor portion is electrically connected to the first via conductor portion via the second via conductor portion.
<6> The integrated LC device according to <5>, in which in a cross section along the thickness direction, a center line of the second via conductor portion is shifted from a center line of the first via conductor portion.
<7> The integrated LC device according to any one of <1> to <6>, in which the third insulating portion includes one layer of insulating layer between the capacitor portion and the inductor portion.
<8> The integrated LC device according to any one of <1> to <7>, in which the inductor portion includes a magnetic layer along the plane direction.
<9> The integrated LC device according to <8>, in which the magnetic layer is wound by a coil conductor when viewed in the plane direction.
<10> The integrated LC device according to <8>, in which the magnetic layer is surrounded by a coil conductor when viewed in the thickness direction.
<11> The integrated LC device according to <8>, in which the coil conductor is surrounded by the magnetic layer.
<12> The integrated LC device according to any one of <8> to <11>, in which the inductor portion includes two or more layers of the magnetic layer in the thickness direction or the plane direction or both of the thickness direction and the plane direction.
<13> The integrated LC device according to any one of <1> to <12>, in which the third insulating portion is made of an inorganic material containing a Si element.
<14> The integrated LC device according to any one of <1> to <13>, in which the capacitor layer further includes: a substrate portion, the substrate portion being provided on the second surface so as to cover the capacitor portion, the first insulating portion, and the first via conductor portion; and a third via conductor portion, the third via conductor portion penetrating through the substrate portion in the thickness direction between the inductor portion and the first via conductor portion, and the inductor portion is electrically connected to the first via conductor portion via the third via conductor portion.
<15> The integrated LC device according to <14>, in which another rewiring layer is provided in the substrate portion between the third via conductor portion and the inductor portion.
<16> The integrated LC device according to any one of <1> to <15>, further including: a power management IC which is electrically connected to the inductor portion on a surface of the inductor layer on a side opposite to the capacitor layer.
<17> A mounting structure including: an interposer which includes the integrated LC device according to any one of <1> to <16>; a package substrate which is arranged on a main surface of the interposer on a side closer to the inductor layer; and a processor which is arranged on a main surface of the interposer on a side closer to the capacitor layer, in which the integrated LC device is located at a position overlapping with the processor in the thickness direction.
<18> The mounting structure according to <17>, in which the interposer further includes a resin layer in which the integrated LC device is embedded.
<19> The mounting structure according to <18>, in which a power management IC is arranged on a surface of the resin layer.
<20> The mounting structure according to <17>, in which the interposer is composed only of the integrated LC device.
<21> The mounting structure according to <20>, in which the integrated LC device further includes a power management IC electrically connected to the inductor portion on a surface of the inductor layer on a side opposite to the capacitor layer.
<22>The mounting structure according to <18> or <20>, further including: a memory which is arranged on the main surface of the interposer on the side closer to the capacitor layer, in which the rewiring layer of the integrated LC device extends to a position overlapping with both of the processor and the memory in the thickness direction, and a power management IC is arranged inside the processor.
1, 1A, 2, 2A, 3 integrated LC device
10 capacitor layer
10a first surface
10b second surface
11 anode
12 cathode
15 rewiring layer
20 rewiring layer
30 inductor layer
31 magnetic layer
32 coil conductor
41 first external terminal
42 second external terminal
43 third external terminal
50 porous layer
50a upper surface
50b lower surface
50c inner surface of groove portion
60 conductor layer
65 insulating layer
70 MIM structure
71 first metal layer
72 second metal layer
73 dielectric layer
80 extended electrode
100, 100A, 100B mounting structure
110, 110A, 110B integrated LC device
120 resin layer
BD bridge die
BP bump
BP1 first bump
BP2 second bump
CAP, CAP1 capacitor portion
CR support member
EC electronic component
GND ground
Load load
IND, IND1, IND2, IND3 inductor portion
INS1 first insulating portion
INS2 second insulating portion
INS3 third insulating portion
IP interposer
MEM memory
PMIC power management integrated circuit
PROC processor
PS package substrate
SBT substrate
ST substrate portion
V1 first via conductor portion
V2 second via conductor portion
V3 third via conductor portion
V4 fourth via conductor portion
V5 fifth via conductor portion
V6 sixth via conductor portion
V7 seventh via conductor portion
VR voltage regulator
WR wiring portion

1. An integrated LC device comprising:
a capacitor layer having a first surface and a second surface, the first surface and the second surface facing each other in a thickness direction;
a rewiring layer provided on the first surface of the capacitor layer; and
an inductor layer provided on the second surface of the capacitor layer, wherein
the capacitor layer includes a capacitor portion having an anode and a cathode, a first insulating portion provided around the capacitor portion, and a first via conductor portion penetrating through the first insulating portion in the thickness direction at a position separate from the capacitor portion in a plane direction orthogonal to the thickness direction,
the rewiring layer includes a wiring portion and a second insulating portion provided around the wiring portion,
the inductor layer includes an inductor portion and a third insulating portion provided around the inductor portion, and
the inductor portion is electrically connected to the anode of the capacitor portion positioned on the first surface of the capacitor layer via the first via conductor portion and the wiring portion.

2. The integrated LC device according to claim 1, wherein the capacitor portion has a MIM structure of metal layer-dielectric layer-metal layer.

3. The integrated LC device according to claim 2, wherein the MIM structure is provided in a porous layer.

4. The integrated LC device according to claim 3, wherein
the porous layer has a groove portion extending in the thickness direction, and
the MIM structure is provided on an inner surface of the groove portion.

5. The integrated LC device according to claim 1, wherein
the inductor layer further includes a second via conductor portion penetrating through the third insulating portion in the thickness direction between the inductor portion and the first via conductor portion, and
the inductor portion is electrically connected to the first via conductor portion via the second via conductor portion.

6. The integrated LC device according to claim 5, wherein in a cross section along the thickness direction, a center line of the second via conductor portion is shifted from a center line of the first via conductor portion.

7. The integrated LC device according to claim 1, wherein the third insulating portion includes one layer of an insulating layer between the capacitor portion and the inductor portion.

8. The integrated LC device according to claim 1, wherein the inductor portion includes a magnetic layer along the plane direction.

9. The integrated LC device according to claim 8, wherein the magnetic layer is wound by a coil conductor when viewed in the plane direction.

10. The integrated LC device according to claim 8, wherein the magnetic layer is surrounded by a coil conductor when viewed in the thickness direction.

11. The integrated LC device according to claim 8, wherein the coil conductor is surrounded by the magnetic layer.

12. The integrated LC device according to claim 8, wherein the inductor portion includes two or more layers of the magnetic layer in the thickness direction or the plane direction or both of the thickness direction and the plane direction.

13. The integrated LC device according to claim 1, wherein the third insulating portion comprises an inorganic material containing a Si element.

14. The integrated LC device according to claim 1, wherein
the capacitor layer further includes: a substrate portion, the substrate portion being provided on the second surface so as to cover the capacitor portion, the first insulating portion, and the first via conductor portion; and a third via conductor portion, the third via conductor portion penetrating through the substrate portion in the thickness direction between the inductor portion and the first via conductor portion, and
the inductor portion is electrically connected to the first via conductor portion via the third via conductor portion.

15. The integrated LC device according to claim 14, wherein another rewiring layer is provided in the substrate portion between the third via conductor portion and the inductor portion.

16. The integrated LC device according to claim 1, further comprising:
a power management IC electrically connected to the inductor portion on a surface of the inductor layer on a side opposite to the capacitor layer.

17. A mounting structure comprising:
an interposer including the integrated LC device according to claim 1;
a package substrate arranged on one main surface of the interposer on a side closer to the inductor layer; and
a processor arranged on another main surface of the interposer on a side closer to the capacitor layer, wherein
the integrated LC device is located at a position overlapping with the processor in the thickness direction.

18. The mounting structure according to claim 17, wherein the interposer further includes a resin layer in which the integrated LC device is embedded.

19. The mounting structure according to claim 18, wherein a power management IC is arranged on a surface of the resin layer.

20. The mounting structure according to claim 17, wherein the interposer is composed only of the integrated LC device.

21. The mounting structure according to claim 20, wherein the integrated LC device further includes a power management IC electrically connected to the inductor portion on a surface of the inductor layer on a side opposite to the capacitor layer.

22. The mounting structure according to claim 18, further comprising:
a memory arranged on the main surface of the interposer on the side closer to the capacitor layer, wherein
the rewiring layer of the integrated LC device extends to a position overlapping with both of the processor and the memory in the thickness direction, and
a power management IC is arranged inside the processor.
